(19) United States
(12) Patent Application Publication
(10) Pub. No.: US 2026/0173585 A1
(43) Pub. Date: Jun. 18, 2026

(54) METHOD FOR MANUFACTURING NITRIDE SEMICONDUCTOR DEVICE

(71) Applicant: Japan Display Inc., Tokyo (JP)

(72) Inventors: Masanobu IKEDA, Tokyo (JP); Masumi NISHIMURA, Tokyo (JP)

(73) Assignee: Japan Display Inc., Tokyo (JP)

(21) Appl. No.: 19/530,592

(22) Filed: Feb. 5, 2026

Related U.S. Application Data
(63) Continuation of application No. PCT/JP2024/026234, filed on Jul. 23, 2024.

(30) Foreign Application Priority Data
Aug. 7, 2023 (JP) 2023-128442

(51) Int. Cl. H10H 20/01; H10H 20/812; H10H 20/825; H10H 20/84

(52) U.S. Cl. CPC H10H 20/019; H10H 20/01335; H10H 20/812; H10H 20/825; H10H 20/84

(57) ABSTRACT

A method for manufacturing a nitride semiconductor device, the method includes bonding a single crystal layer to an amorphous glass substrate; forming a light absorbing layer on the single crystal layer; forming a nitride semiconductor stack on the light absorbing layer; irradiating laser light from a side of the amorphous glass substrate opposite to the single crystal layer side to separate the nitride semiconductor stack from the single crystal layer, thereby exposing a surface of the nitride semiconductor stack on the single crystal layer side; and cleaning the exposed surface of the nitride semiconductor stack. Forming the nitride semiconductor stack includes forming at least one gallium nitride-based semiconductor layer on the light absorbing layer, and the light absorbing layer is formed of a material having a light absorption band for the laser light and allowing heteroepitaxial growth of the gallium nitride-based semiconductor layer.

### CROSS-REFERENCE TO RELATED APPLICATIONS

This application is a Continuation of International Patent Application No. PCT/JP2024/026234, filed on Jul. 23, 2024, which claims the benefit of priority to Japanese Patent Application No. 2023-128442, filed on Aug. 7, 2023, the entire contents of which are incorporated herein by reference.

### FIELD

An embodiment of the present invention relates to a nitride semiconductor device and a method for manufacturing the nitride semiconductor device having a nitride semiconductor layer formed on an amorphous glass substrate.

### BACKGROUND

A gallium nitride-based semiconductor film forming a light emitting diode is formed on a sapphire substrate at a temperature of 800° C. to 1100° C. by a metal organic chemical vapor deposition (MOCVD) method, a hydride vapor phase epitaxy (HVPE) method, or the like. Since sapphire substrates are expensive, costs can be reduced if the film can be formed using an inexpensive substrate. Therefore, development is underway to form a gallium nitride-based semiconductor film on a glass substrate used in the manufacture of displays. For example, a technique is disclosed in which a silicon oxide film is formed on a glass substrate, an amorphous silicon film and an AlₓGa₁₋ₓN buffer layer are formed on the silicon oxide film, and a nitride-based compound semiconductor having crystallinity is formed thereon at a temperature of approximately 700° C. to 850° C. (refer to Japanese laid-open patent publication No. 2000-124140).

### SUMMARY

A method for manufacturing a nitride semiconductor device in an embodiment according to the present invention, the method includes bonding a single crystal layer to an amorphous glass substrate; forming a light absorbing layer on the single crystal layer; forming a nitride semiconductor stack on the light absorbing layer; irradiating laser light from a side of the amorphous glass substrate opposite to the single crystal layer side to separate the nitride semiconductor stack from the single crystal layer, thereby exposing a surface of the nitride semiconductor stack on the single crystal layer side; and cleaning the exposed surface of the nitride semiconductor stack. Forming the nitride semiconductor stack includes forming at least one gallium nitride-based semiconductor layer on the light absorbing layer, and the light absorbing layer is formed of a material having a light absorption band for the laser light and allowing heteroepitaxial growth of the gallium nitride-based semiconductor layer.

### BRIEF DESCRIPTION OF DRAWINGS

FIG. 1 is a cross-sectional view illustrating a nitride semiconductor device and a laminated substrate according to an embodiment of the present invention.

FIG. 2A is a flowchart illustrating a method for manufacturing a nitride semiconductor device according to an embodiment of the present invention.

FIG. 2B is a flowchart illustrating a method for manufacturing a nitride semiconductor device according to an embodiment of the present invention.

FIG. 2C is a flowchart illustrating a method for manufacturing a nitride semiconductor device according to an embodiment of the present invention.

FIG. 3A is a cross-sectional view illustrating a method for manufacturing a nitride semiconductor device according to an embodiment of the present invention.

FIG. 3B is a cross-sectional view illustrating a method for manufacturing a nitride semiconductor device according to an embodiment of the present invention.

FIG. 3C is a cross-sectional view illustrating a method for manufacturing a nitride semiconductor device according to an embodiment of the present invention.

FIG. 3D is a cross-sectional view illustrating a method for manufacturing a nitride semiconductor device according to an embodiment of the present invention.

FIG. 3E is a cross-sectional view illustrating a method for manufacturing a nitride semiconductor device according to an embodiment of the present invention.

FIG. 3F is a cross-sectional view illustrating a method for manufacturing a nitride semiconductor device according to an embodiment of the present invention.

FIG. 3G is a cross-sectional view illustrating a method for manufacturing a nitride semiconductor device according to an embodiment of the present invention.

FIG. 3H is a cross-sectional view illustrating a method for manufacturing a nitride semiconductor device according to an embodiment of the present invention.

FIG. 4 is a graph showing a relationship between band gaps and lattice constants of various nitride materials.

FIG. 5 is a cross-sectional view illustrating a nitride semiconductor device according to an embodiment of the present invention.

FIG. 6A is a cross-sectional view illustrating a method for manufacturing a nitride semiconductor device according to an embodiment of the present invention.

FIG. 6B is a cross-sectional view illustrating a method for manufacturing a nitride semiconductor device according to an embodiment of the present invention.

FIG. 6C is a cross-sectional view illustrating a method for manufacturing a nitride semiconductor device according to an embodiment of the present invention.

FIG. 7A is a flowchart illustrating a method for manufacturing a nitride semiconductor device according to an embodiment of the present invention.

FIG. 7B is a flowchart illustrating a method for manufacturing a nitride semiconductor device according to an embodiment of the present invention.

FIG. 8A is a cross-sectional view illustrating a method for manufacturing a nitride semiconductor device according to an embodiment of the present invention.

FIG. 8B is a cross-sectional view illustrating a method for manufacturing a nitride semiconductor device according to an embodiment of the present invention.

### DESCRIPTION OF EMBODIMENTS

Hereinafter, embodiments of the present invention will be described with reference to the drawings. However, the present invention can be implemented in many different forms and should not be construed as being limited to the description of the embodiments exemplified below. Although the drawings may schematically represent the width, thickness, shape, and the like of each component compared to the actual form in order to clarify the explanation, they are merely examples and do not limit the interpretation of the present invention. In addition, in the present specification and each drawing, the same reference numerals (or reference numerals followed by A, B, or a, b, etc.) are applied to elements similar to those described above with reference to the previously described drawings, and detailed descriptions thereof may be omitted as appropriate. Furthermore, the terms “first,” “second,” and the like attached to each element are convenient labels used to distinguish the elements and have no further meaning unless otherwise specified.

### First Embodiment

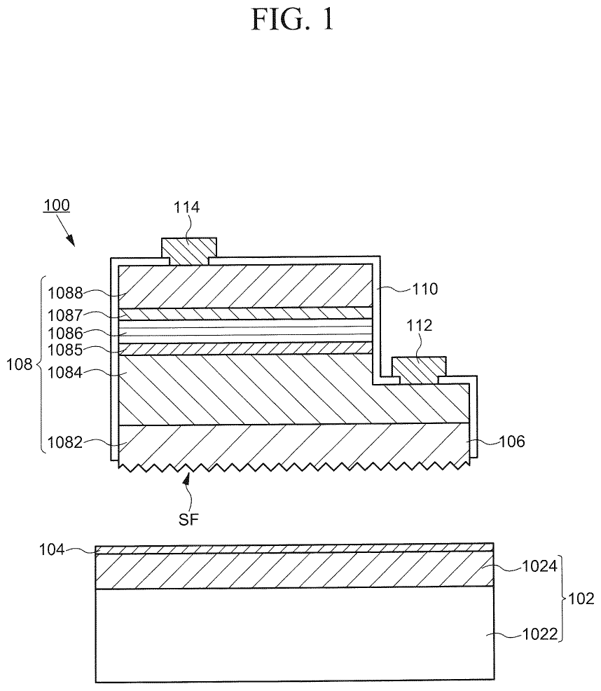

FIG. 1 is a cross-sectional view illustrating a nitride semiconductor device 100 and a laminated substrate 102 according to an embodiment of the present invention. The nitride semiconductor device 100 is fabricated on the laminated substrate 102. The nitride semiconductor device 100 is separated from the laminated substrate 102 in a later stage of the manufacturing process. For example, the nitride semiconductor device 100 is separated from the laminated substrate 102 when the nitride semiconductor device 100 is mounted on a predetermined circuit board, a die, a backplane substrate, or the like.

The nitride semiconductor device 100 includes a nitride semiconductor layer made of a nitride of a Group 13 element of the periodic table. For example, the nitride semiconductor device 100 includes at least one gallium nitride layer. On the other hand, the laminated substrate 102 has a structure in which a single crystal layer 1024 is bonded onto an amorphous glass substrate 1022.

The amorphous glass substrate 1022 and the single crystal layer 1024 constituting the laminated substrate 102 are formed of different materials. For the amorphous glass substrate 1022, glass having a low content of alkali metal components is used in order to prevent metal contamination to the nitride semiconductor device 100. Specifically, the amorphous glass substrate 1022 is preferably amorphous glass composed of, for example, aluminoborosilicate glass or aluminosilicate glass. The amorphous glass substrate 1022 is used in liquid crystal displays and organic electroluminescence displays, and a large-area glass substrate called mother glass provided in the market can be applied.

There is no limitation on the thickness of the amorphous glass substrate 1022, for example, an amorphous glass substrate 1022 having a thickness of 0.5 mm to 1.0 mm can be applied. The amorphous glass substrate 1022 is generally amorphous having no crystal structure, but a crystal structure may exist in a minute region. The amorphous glass substrate 1022 preferably has heat resistance capable of withstanding a process temperature (maximum processing temperature) of the nitride semiconductor device 100. For example, when the process temperature (maximum processing temperature) of the nitride semiconductor device 100 is less than 650° C., the heat resistance of the amorphous glass substrate 1022 is preferably at least 650° C. An upper limit of a coefficient of thermal expansion of the amorphous glass substrate 1022 is preferably less than 4.2×10⁻⁶/K (4.2 ppm/K), and more preferably less than 4.0×10⁻⁶/K (4.0 ppm/K). A lower limit of the coefficient of thermal expansion of the amorphous glass substrate 1022 is preferably greater than 3.0×10⁻⁶/K (3.0 ppm/K), and more preferably greater than 3.5×10⁻⁶/K (3.5 ppm/K).

The single crystal layer 1024 is formed of a single crystal material that lattice-matches a nitride semiconductor containing a nitride of a Group 13 element of the periodic table. It is preferable that a lattice constant mismatch between the single crystal layer 1024 and the nitride semiconductor containing the nitride of the Group 13 element of the periodic table is 15% or less, and preferably 5.0% or less. Specifically, the single crystal layer 1024 is formed by thinning a single crystal substrate such as a single crystal sapphire substrate or a ScAlMgO₄ single crystal substrate. The single crystal layer 1024 preferably has a thickness of 200 μm or less, and preferably 100 μm or less. For example, the single crystal layer 1024 may be thinned after a single crystal substrate having a thickness of about 400 μm is bonded to the amorphous glass substrate 1022, or the single crystal substrate 103 may be bonded to the amorphous glass substrate 1022 after being thinned.

As shown in FIG. 1, the laminated substrate 102 and the nitride semiconductor device 100 are separated such that the single crystal layer 1024 remains on the amorphous glass substrate 1022 side. As will be described later, in order to separate the nitride semiconductor device 100 formed on the laminated substrate 102, laser light is irradiated from the amorphous glass substrate 1022 side. Specifically, in order to separate the nitride semiconductor device 100 from the laminated substrate 102, laser light having an energy larger than a band gap of gallium nitride (3.4 eV, 365 nm in terms of wavelength) (laser light having a wavelength shorter than 365 nm) is irradiated.

In order to transmit laser light in an ultraviolet range, a band gap of the amorphous glass substrate 1022 is preferably larger than a band gap of gallium nitride (3.4 eV, 365 nm in terms of wavelength). In particular, it is preferable that the amorphous glass substrate 1022 and the single crystal layer 1024 have a transmittance of 80% or more for a third harmonic (355 nm) of a YAG laser and laser light of a solid-state laser having an oscillation wavelength of 345 nm. With respect to wavelengths of such laser light, aluminoborosilicate glass and aluminosilicate glass as exemplified above as the amorphous glass substrate 1022 are preferable because they have a transmittance of 80% or more.

In addition, since a band gap of sapphire used as the single crystal layer 1024 is 8 eV or more and a band gap of ScAlMgO₄ is 6.2 eV, they have a sufficiently wide band gap with respect to energy of light of a third harmonic (355 nm) of a YAG laser and a solid-state laser having an oscillation wavelength of 345 nm.

As shown in FIG. 1, a buffer layer 104 formed of c-axis oriented aluminum nitride or the like may be formed on a top surface of the single crystal layer 1024. The buffer layer 104 is provided to control the crystallinity of a nitride semiconductor layer made of a nitride of a Group 13 element of the periodic table formed on the top surface.

The nitride semiconductor device 100 includes a nitride semiconductor stack 108, a passivation layer 110, an n-electrode 112, and a p-electrode 114. FIG. 1 shows a structure in which an undoped nitride semiconductor layer 1082, an n-type nitride semiconductor layer 1084, an electron injection layer 1085, a light emitting layer 1086, a hole injection layer 1087, and a p-type nitride semiconductor layer 1088 are stacked as an example of the nitride semiconductor stack 108. At least one of the undoped nitride semiconductor layer 1082, the n-type nitride semiconductor layer 1084, and the p-type nitride semiconductor layer 1088 is a gallium nitride layer. The gallium nitride layer has crystallinity. The light emitting layer 1086 has a structure in which a plurality of types of gallium nitride-based semiconductor layers having different band gaps are stacked so that a quantum well is formed.

As is apparent from such a structure, one aspect of the nitride semiconductor device 100 shown in this embodiment is a device that functions as a light emitting diode (LED). Note that the structure of the nitride semiconductor stack 108 shown in FIG. 1 is an example, and another laminated structure may be employed as long as it is capable of functioning as a light emitting diode.

The nitride semiconductor device 100 may be provided with a passivation layer 110 covering the nitride semiconductor stack 108. The passivation layer 110 has openings in a region in contact with the n-type nitride semiconductor layer 1084 and in a region in contact with the p-type nitride semiconductor layer 1088. In these openings, an n-electrode 112 forms a contact with the n-type nitride semiconductor layer 1084, and a p-electrode 114 forms a contact with the p-type nitride semiconductor layer 1088. Next, details of each layer constituting the nitride semiconductor device 100 shown in FIG. 1 will be described.

The nitride semiconductor stack 108 includes an undoped nitride semiconductor layer 1082, an n-type nitride semiconductor layer 1084, a light emitting layer 1086, and a p-type nitride semiconductor layer 1088. The nitride semiconductor stack 108 may also include an electron injection layer 1085 and a hole injection layer 1087.

The undoped nitride semiconductor layer 1082 is provided to reduce crystal dislocations of the n-type nitride semiconductor layer 1084 formed thereon. The undoped nitride semiconductor layer 1082 is formed using the same semiconductor material as the n-type nitride semiconductor layer 1084. For example, the undoped nitride semiconductor layer 1082 is formed of gallium nitride. Note that the term “undoped” is intended to mean that impurity elements for the purpose of carrier control are not intentionally included, and the undoped nitride semiconductor layer 1082 may inevitably contain impurity elements such as oxygen, carbon, and hydrogen. There is no particular limitation on a film thickness of the undoped nitride semiconductor layer 1082.

The n-type nitride semiconductor layer 1084 is doped with a donor impurity such as silicon (Si) or germanium (Ge) to impart n-type conductivity to the nitride semiconductor. For example, a gallium nitride layer doped with silicon (Si) can be used as the n-type nitride semiconductor layer 1084. Although there is no particular limitation on a film thickness of the n-type nitride semiconductor layer 1084, it preferably has a film thickness of, for example, 50 nm or more and less than 3000 nm.

The light emitting layer 1086 is a region where electrons transported from the n-type nitride semiconductor layer 1084 and holes transported from the p-type nitride semiconductor layer 1088 recombine to emit light. The light emitting layer 1086 has a multiple quantum well (MQW) structure. It is preferable that the light emitting layer 1086 has a quantum well structure in which, for example, gallium nitride (GaN) layers and indium gallium nitride (InGaN) layers are alternately stacked.

The p-type nitride semiconductor layer 1088 is doped with an acceptor impurity such as magnesium (Mg) in order to impart p-type conductivity to the nitride semiconductor film. In addition, zinc (Zn) may be used as the acceptor impurity for imparting the p-type conductivity. For example, a gallium nitride layer doped with magnesium (Mg) can be used as the p-type nitride semiconductor layer 1088. Although there is no particular limitation on a film thickness of the p-type nitride semiconductor layer 1088, it preferably has a film thickness of, for example, 50 nm or more and less than 500 nm.

The electron injection layer 1085 is formed of an n-type nitride semiconductor. For example, the electron injection layer 1085 can be formed of n-type indium gallium nitride or n-type gallium nitride. The hole injection layer 1087 is formed of a p-type nitride semiconductor. For example, the hole injection layer 1087 can be formed of p-type indium gallium nitride or p-type gallium nitride. The electron injection layer 1085 is provided to lower an electron injection barrier to the light emitting layer 1086, and the hole injection layer 1087 is provided to lower a hole injection barrier to the light emitting layer 1086. By providing the electron injection layer 1085, electron injection efficiency from the n-type nitride semiconductor layer 1084 to the light emitting layer 1086 can be increased, and by providing the hole injection layer 1087, hole injection efficiency from the p-type nitride semiconductor layer 1088 to the light emitting layer 1086 can be increased.

Some of the layers constituting the nitride semiconductor stack 108 may be omitted. Further, a stacking order of the nitride semiconductor stack 108 is not limited to the order shown in FIG. 1. The stacking order and a laminated structure of the nitride semiconductor stack 108 can be modified in various ways in order to exhibit a function of the nitride semiconductor device 100.

The passivation layer 110 is formed of a silicon oxide film, a silicon nitride film, or aluminum oxide material. The passivation layer 110 may have a structure in which a silicon oxide film and a silicon nitride film are stacked. The passivation layer 110 is provided so as to cover the entire nitride semiconductor stack 108.

The n-electrode 112 and the p-electrode 114 are provided on the passivation layer 110. The n-electrode 112 forms an ohmic contact with the n-type nitride semiconductor layer 1084 in an opening formed in the passivation layer 110 exposing the n-type nitride semiconductor layer 1084, and the p-electrode 114 forms an ohmic contact with the p-type nitride semiconductor layer 1088 through an opening formed in the passivation layer 110 exposing the p-type nitride semiconductor layer 1088.

When the work function of the n-type nitride semiconductor layer 1084 is 3 eV to 4 eV, the n-electrode 112 is formed of a conductive material having a work function of 4.5 eV or more, such as nickel (Ni), gold (Au), platinum (Pt), silver (Ag), and p-type silicon. The n-electrode 112 may have a metal layer such as aluminum (Al) laminated on a layer formed of these conductive materials. The n-electrode 112 may additionally include, for example, copper (Cu) and a barrier metal layer for preventing diffusion of the copper (Cu). The barrier metal layer is formed of titanium (Ti), titanium nitride (TiN), tantalum (Ta), or tantalum nitride (TaN) or the like. The n-electrode 112 may have, for example, a structure in which titanium (Ti), titanium nitride (TiN), and copper (Cu) are stacked in this order.

The p-electrode 114 is formed of a metal material such as gold (Au), a titanium (Ti)-gold (Au) alloy, or nickel (Ni), or a transparent conductive film such as indium tin oxide (ITO). As a material forming the p-electrode 114, for example, a metal material having a work function of less than 4.5 eV, such as aluminum (Al) or titanium (Ti), is selected. Although not shown, the p-electrode 114 may be formed of a conductive metal oxide material such as indium oxide (In₂O₃), zinc oxide (ZnO), indium tin oxide (ITO), or indium antimony oxide (ATO) on a top surface of the p-type nitride semiconductor layer 1088.

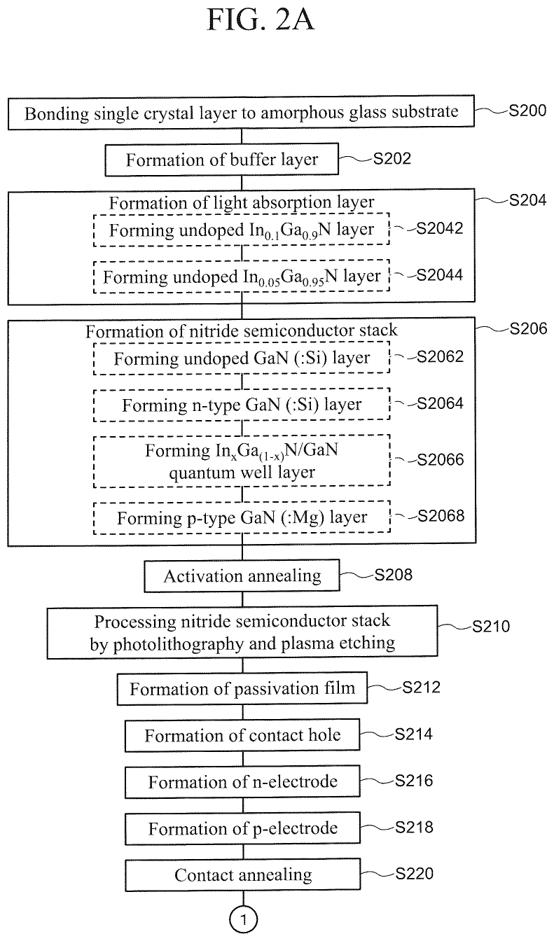

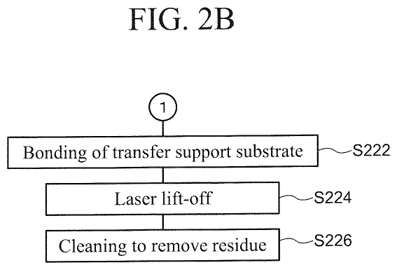

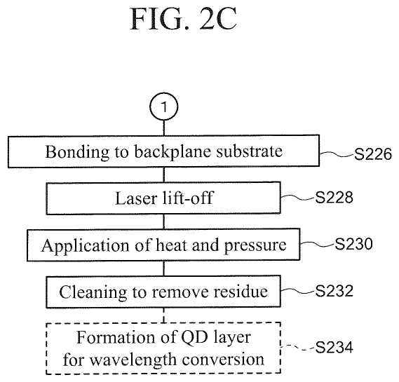

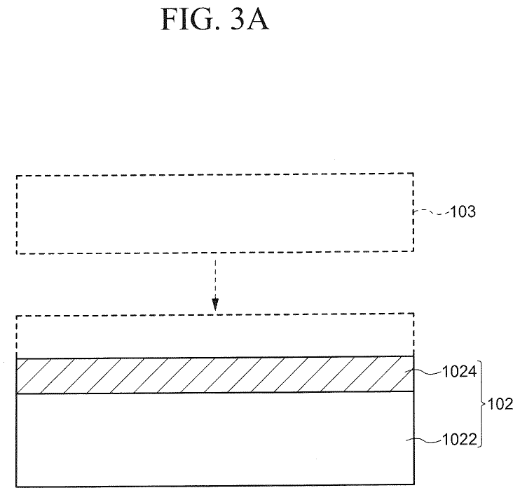

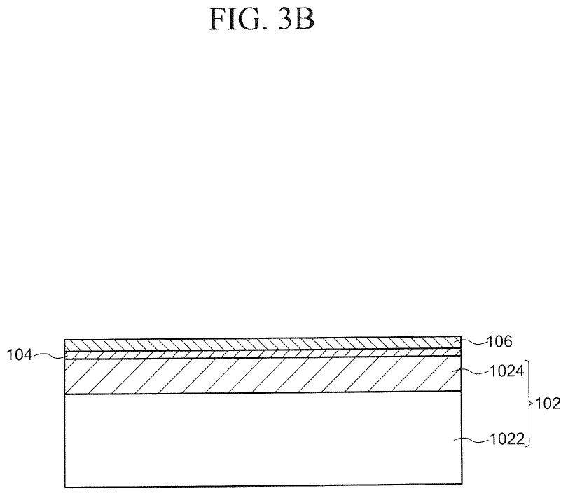

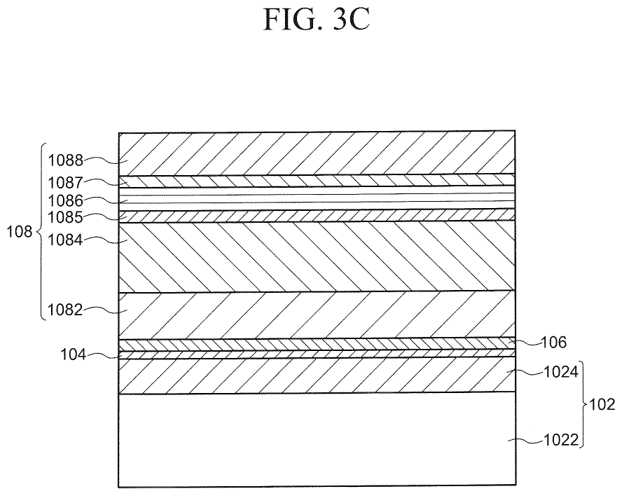

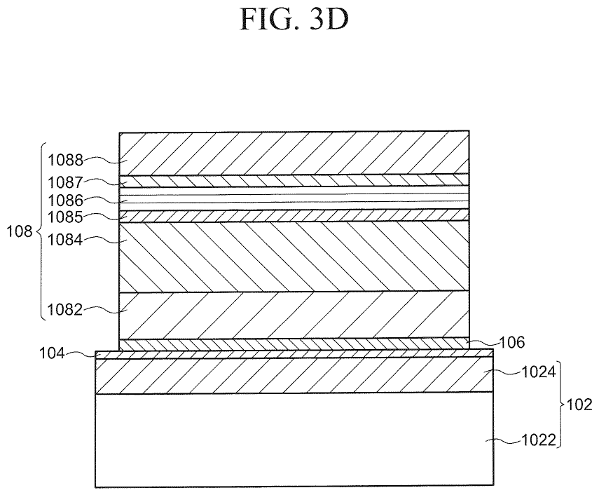

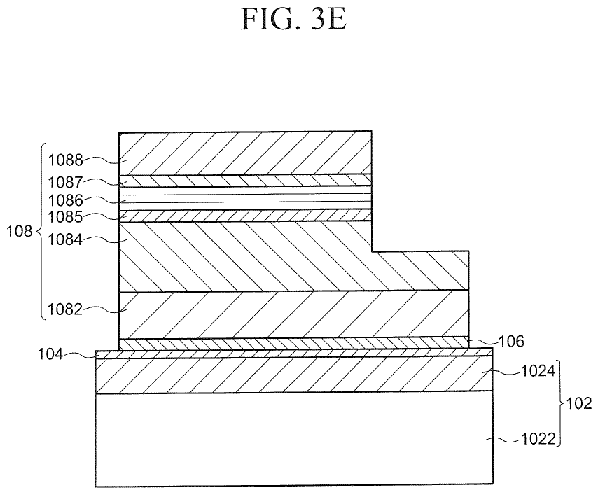

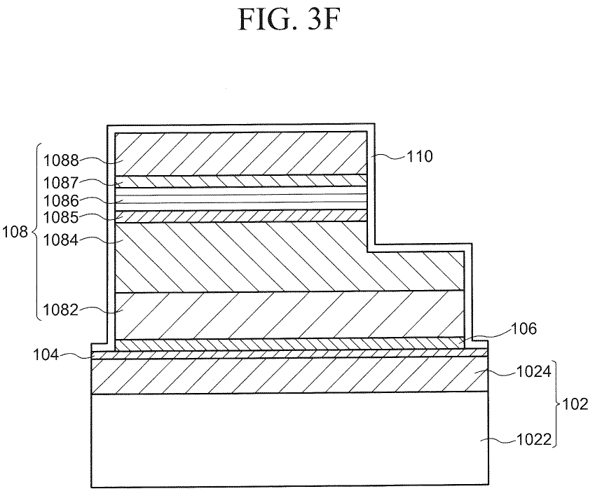

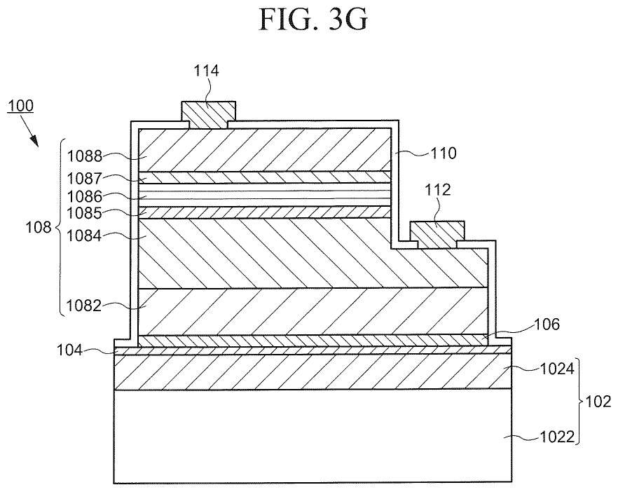

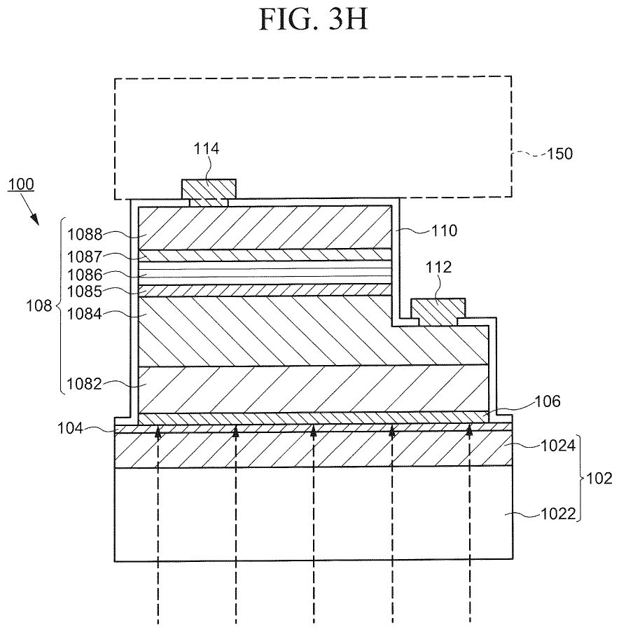

Next, an example of a method for manufacturing the laminated substrate 102 and the nitride semiconductor device 100 shown in FIG. 1 will be described. FIG. 2A and FIG. 2B show flowcharts explaining the method for manufacturing the nitride semiconductor device 100 on the laminated substrate 102. Further, FIG. 3A to FIG. 3H show cross-sectional views for explaining each step. Hereinafter, description will be given with reference to these drawings as appropriate.

First, the single crystal layer 1024 is bonded to the amorphous glass substrate 1022 to fabricate the laminated substrate 102 (FIG. 2A, S200). FIG. 3A shows a state in which the single crystal layer 1024 is bonded to the amorphous glass substrate 1022. The single crystal layer 1024 is bonded to the amorphous glass substrate 1022 by direct bonding without using an adhesive or the like.

FIG. 3A shows a stage of forming the single crystal layer 1024 by thinning the single crystal substrate 103 by polishing after bonding the single crystal substrate 103 to the amorphous glass substrate 1022. A direct bond can be formed by cleaning surfaces of the amorphous glass substrate 1022 and the single crystal substrate 103 to form clean surfaces having hydroxyl groups on the surfaces of both substrates, and bonding them together. In order to strengthen the bonding, a heat treatment may be performed at a temperature equal to or lower than a heat resistance temperature of the amorphous glass substrate 1022 after bonding the single crystal substrate 103 and the amorphous glass substrate 1022 together. The clean surfaces having hydroxyl groups can be formed by cleaning the amorphous glass substrate 1022 and the single crystal substrate 103 with a solution using a mixture of sulfuric acid or hydrochloric acid and hydrogen peroxide solution. Further, the direct bond can be similarly formed by activating the surfaces of the amorphous glass substrate 1022 and the single crystal substrate 103 by performing a plasma treatment with oxygen plasma or rare gas plasma such as argon.

Note that FIG. 3A shows a step of forming the single crystal layer 1024 by thinning the single crystal substrate 103 by polishing after bonding the single crystal substrate 103 to the amorphous glass substrate 1022. Instead of this step, a step of thinning the single crystal substrate 103 before forming a bond and bonding the thinned single crystal layer 1024 to the amorphous glass substrate 1022 may be employed.

Next, a buffer layer 104 is formed on the single crystal layer 1024 (FIG. 2A, S202), and a light absorption layer 106 is further formed (FIG. 2A, S204). FIG. 3B shows the buffer layer 104 and the light absorption layer 106 formed on the single crystal layer 1024. The buffer layer 104 is provided to alleviate lattice mismatch between the single crystal layer 1024 and a nitride semiconductor layer formed thereon. For example, when the single crystal layer 1024 is formed of single crystal sapphire and a gallium nitride layer is formed as the nitride semiconductor layer, if a lattice constant of sapphire is 0.2747 nm (2.747 Å: lattice constant of aluminum oxide (as a hexagonal crystal)) and a lattice constant of gallium nitride is 0.3189 nm (3.189 Å), there is a lattice mismatch of about 14%. It is preferable that the buffer layer 104 is provided to alleviate this lattice mismatch.

The buffer layer 104 can be formed of, for example, aluminum nitride (lattice constant: 0.3122 nm (3.122 Å)) which is closer to the lattice constant of gallium nitride. Lattice mismatch can be alleviated by providing the buffer layer 104 formed of aluminum nitride on the single crystal layer 1024 formed of sapphire.

The buffer layer 104 preferably has a hexagonal close-packed structure, a face-centered cubic structure, or a similar structure thereto. Here, the structure similar to the hexagonal close-packed structure or the face-centered cubic structure refers to a crystal structure in which the c-axis is not 90° with respect to the a-axis and the b-axis. Since the buffer layer 104 has such a structure, crystal growth of a nitride semiconductor film in a c-axis direction is promoted, and crystallinity can be improved.

In addition to aluminum nitride (AlN), zinc oxide (ZnO), lithium niobate (LiNbO), BiLaTiO, SrFeO, BiFeO, BaFeO, ZnFeO, PMnN-PZT, biological apatite (BAp), or the like may be used as the buffer layer 104. The buffer layer 104 can be formed by a sputtering method, a vapor phase growth method, or the like. The buffer layer 104 may be a single layer formed of the insulating material as described above or may have a structure in which a plurality of layers is stacked.

When the refractive index of the single crystal layer 1024 (in the case of sapphire) is 1.77 and the refractive index of the aluminum nitride layer formed as the buffer layer 104 is 2.05, these refractive indices are intermediate between the refractive index of 1.51 of the amorphous glass substrate 1022 and the refractive index of 2.4 of the gallium nitride layer. Accordingly, it is possible to expect that the buffer layer 104 will reduce the refractive index stepwise from the gallium nitride layer to the amorphous glass substrate 1022, thereby suppressing reflections at the interface.

The light absorption layer 106 is used for detaching the nitride semiconductor device 100 formed on an upper layer side thereof by irradiation with laser light. Therefore, the light absorption layer 106 is preferably formed of a material having a sufficiently high absorption coefficient for a wavelength of the laser light. In other words, the light absorption layer 106 is preferably formed of a material having a band gap energy smaller than the energy of the laser light. When a third harmonic of a YAG laser (355 nm) or a solid-state laser having an oscillation wavelength of 345 nm is used as the laser light, it is preferable to form the light absorption layer of a material having a band gap of 3.5 eV or less. Further, it is preferable that the light absorption layer 106 has a lattice constant comparable to a lattice constant of a nitride semiconductor layer forming the nitride semiconductor stack 108 formed thereon.

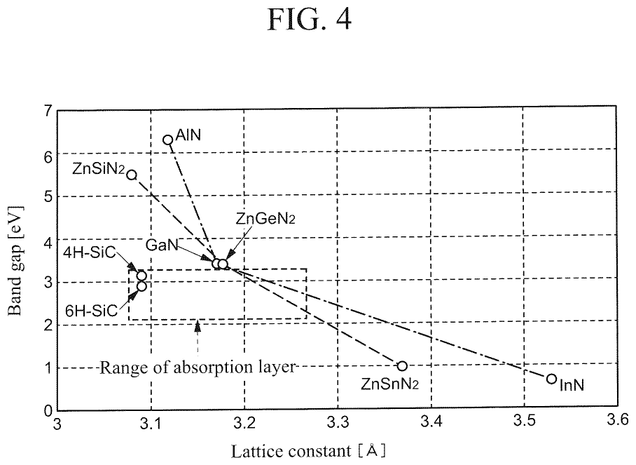

FIG. 4 shows a graph showing a relationship between a band gap and a lattice constant of various nitride materials. A rectangular frame shown in the graph of FIG. 4 indicates a range suitable for the light absorption layer 106. The graph shown in FIG. 4 indicates that a preferable range for the light absorption layer 106 is a range in which the lattice constant is 3.07 to 3.27 and the band gap is 2.2 eV to 3.3 eV.

As shown in the graph of FIG. 4, it can be seen that, compared to gallium nitride (GaN) which is a nitride of a Group 13 element of the periodic table, aluminum nitride (AlN), which is a nitride of aluminum (Al) that is the same Group 13 element, has a wider band gap, while indium nitride (InN), which is a nitride of indium (In), tends to have a smaller band gap and a larger lattice constant. Therefore, it is expected that a material suitable for the light absorption layer 106 can be obtained by adding indium (In) to gallium nitride (GaN) and adjusting a composition ratio of gallium (Ga) and indium (In). For example, in indium gallium nitride (InxGa1−xN), when 0.05≤x≤0.25, it is expected that a material suitable for the light absorption layer 106 can be obtained based on the relationship between the lattice constant and the band gap. Assuming a case where a gallium nitride (GaN) layer is formed on the light absorption layer 106, it can be seen from the graph shown in FIG. 4 that zinc germanium nitride (ZnGeN₂) has a relatively close band gap and lattice constant.

Further, from the graph of FIG. 4, it can be seen that when germanium (Ge) in zinc germanium nitride (ZnGeN₂) is replaced with silicon (Si), the lattice constant tends to decrease and the band gap tends to widen (ZnSiN₂), and when replaced with tin (Sn), the lattice constant tends to increase and the band gap tends to narrow (ZnSnN₂). Therefore, it is expected that a material suitable for the light absorption layer 106 can be obtained by adding tin (Sn) to zinc germanium nitride (ZnGeN₂) and adjusting a composition ratio of germanium (Ge) and tin (Sn). For example, in zinc germanium tin nitride (ZnGeₓSn₁₋ₓN₂), when 0.60≤x≤0.90, it is expected that a material suitable for the light absorption layer 106 can be obtained based on the relationship between the lattice constant and the band gap. Both indium gallium nitride (InₓGa₁₋ₓN) and zinc germanium tin nitride (ZnGeₓSn₁₋ₓN₂) can be formed by a sputtering method, and the composition can be controlled by adjusting the composition of a target material.

As shown in the graph of FIG. 4, it is also possible to use 4H-SiC (band gap: 3.265 eV, lattice constant: 3.07 Å (a-axis)) or 6H-SiC (band gap: 3.024 eV, lattice constant: 3.08 Å (a-axis)) as the light absorption layer 106.

The light absorption layer 106 may be formed of a plurality of layers having different compositions. For example, as shown in the FIG. 2A flowchart, as the light absorption layer 106, a first undoped indium gallium nitride (In_{0.1}Ga_{0.9}N) layer may be formed from the buffer layer 104 side (FIG. 2A, S2042), and further, a second undoped indium gallium nitride (In_{0.05}Ga_{0.95}N) layer may be formed (FIG. 2A, S2044). In this manner, when indium gallium nitride is used as the light absorption layer 106, by decreasing the concentration of indium toward the nitride semiconductor stack, lattice mismatch with the nitride semiconductor layer formed in an upper layer can be alleviated while ensuring sufficient light absorption.

FIG. 2A illustrates a case where indium gallium nitride (InₓGa₁₋ₓN) is used as the light absorption layer 106, but the same applies to a case where zinc germanium tin nitride (ZnGeₓSn₁₋ₓN₂) is used.

It is preferable that the light absorption layer 106 formed of such a material has a thickness such that the laser light does not penetrate to the nitride semiconductor device 100 in a step of detaching by irradiation with laser light. It is preferable that the light absorption layer 106 has a film thickness of, for example, 50 nm to 500 nm.

Next, a nitride semiconductor stack 108 is formed (FIG. 2A, S206). FIG. 3C shows the nitride semiconductor stack 108 formed on the light absorption layer 106. An undoped nitride semiconductor layer 1082, an n-type nitride semiconductor layer 1084, a light emitting layer 1086, and a p-type nitride semiconductor layer 1088 constituting the nitride semiconductor stack 108 are formed in this order by a sputtering method (S2062 to S2068 shown in FIG. 2A). For example, the undoped nitride semiconductor layer 1082 is formed of undoped gallium nitride, the n-type nitride semiconductor layer 1084 is formed of gallium nitride to which silicon (Si) is added as a donor impurity, and the p-type nitride semiconductor layer 1088 is formed of gallium nitride to which magnesium (Mg) is added as an acceptor impurity. The light emitting layer 1086 is formed to have a quantum well structure by alternately stacking gallium nitride (GaN) layers and indium gallium nitride (InₓGa₁₋ₓ) layers. Further, as described above, an electron injection layer 1085 may be formed between the n-type nitride semiconductor layer 1084 and the light emitting layer 1086, and a hole injection layer may be formed between the light emitting layer 1086 and the p-type nitride semiconductor layer 1088.

Taking a gallium nitride layer as an example of the nitride semiconductor layer, a gallium nitride sintered body is used as a sputtering target for formation of the gallium nitride layer by a sputtering method. An inert gas such as argon (Ar) or krypton (Kr) is used as a sputtering gas, and a substrate heating temperature during film formation can be selected in a range of 400° C. to 600° C. In the present embodiment, since the laminated substrate 102 provided with the single crystal layer 1024 that easily achieves lattice matching with a nitride semiconductor such as gallium nitride is used, a nitride semiconductor layer having favorable crystallinity can be formed by the sputtering method even if the film formation temperature is relatively low.

It is preferable that the nitride semiconductor stack 108 shown in FIG. 3C is formed continuously in a vacuum using a multi-chamber sputtering apparatus. By installing sputtering targets suitable for film formation of the undoped nitride semiconductor layer 1082, the n-type nitride semiconductor layer 1084, the light emitting layer 1086, and the p-type nitride semiconductor layer 1088 (and further, the electron injection layer 1085 and the hole injection layer 1087) in respective chambers of the multi-chamber sputtering apparatus, these layers can be formed continuously in a vacuum.

After the nitride semiconductor stack 108 is formed, a heat treatment for activation may be performed (FIG. 2A: S208). It is preferable that the heat treatment is performed in a nitrogen atmosphere at a temperature of 600° C. to less than 800° C. By this heat treatment, impurities for carrier control in the n-type nitride semiconductor layer 1084 and the p-type nitride semiconductor layer 1088 are activated, and improvement in conductivity can be achieved.

Through the steps described above, the buffer layer 104, the light absorption layer 106, and the nitride semiconductor stack 108 are formed over substantially the entire surface of the laminated substrate 102.

Next, the nitride semiconductor stack 108 is processed by photolithography and etching so that the nitride semiconductor stack 108 remains in an island shape in a region where a nitride semiconductor device is to be formed, and further so that a contact can be formed with the n-type nitride semiconductor layer 1064 (FIG. 2A: S210).

FIG. 3D shows a state in which the nitride semiconductor stack 108 has been etched. A resist pattern having a predetermined shape is formed on the nitride semiconductor stack 108 by photolithography, and then etching is performed. Although dry etching or wet etching can be selected for the etching, it is preferable to select dry etching for microfabrication. As an etching gas, a chlorine-based etching gas such as Cl₂ can be used.

Note that since the light absorption layer 106 has a composition similar to that of the nitride semiconductor layer forming the nitride semiconductor stack 108, the light absorption layer 106 may be etched simultaneously by this etching. Since the single crystal layer 1024 has a high selectivity with respect to the etching gas and has a sufficiently large film thickness, the single crystal layer 1024 is not etched and can remain on the amorphous glass substrate 1022. Further, although it is preferable that the buffer layer 104 remains, since the buffer layer 104 is relatively thin, it may be etched simultaneously during this etching.

FIG. 3E shows a stage of forming a contact region for the n-electrode 112 to form a contact with the n-type nitride semiconductor layer 1084. The p-type nitride semiconductor layer 1088 and the light emitting layer 1086 (and the hole injection layer 1087 and the electron injection layer 1085) are etched to expose an upper surface of the n-type nitride semiconductor layer 1084. Since the upper surface of the n-type nitride semiconductor layer 1084 is exposed by the etching, this upper surface can be used as a region where the n-electrode 112 forms a contact.

Next, the passivation layer 110 is formed (FIG. 2A: S212). FIG. 3F shows a stage of forming the passivation layer 110 to cover the nitride semiconductor stack 108. The passivation layer 110 can be formed of an inorganic insulating material such as silicon nitride. Note that the passivation layer 110 is not limited to being formed by a sputtering method, and can be produced by, for example, a CVD method.

Next, contact holes are formed in the passivation layer 110 (FIG. 2A: S214), and the n-electrode 112 is formed (FIG. 2A: S216) and the p-electrode 114 is formed (FIG. 2A: S218). Further, annealing is performed so that the n-electrode 112 and the p-electrode 114 make ohmic contact with the respective nitride semiconductor layers (FIG. 2A: S220).

The contact holes are formed in the passivation layer 110 to expose an upper surface of the n-type nitride semiconductor layer 1084 and an upper surface of the p-type nitride semiconductor layer 1088. Then, the n-electrode 112 and the p-electrode 114 are formed. Since a conductive material suitable for forming the n-electrode 112 is different from a conductive material suitable for forming the p-electrode 114, these two types of electrodes are produced in separate steps. Note that there is no limitation to the order for producing the n-electrode 112 and the p-electrode 114, and the p-electrode 114 may be produced first. Thereafter, it is preferable to perform annealing for reducing contact resistance of the n-electrode 112 and the p-electrode 114.

Through the steps described above, the nitride semiconductor device 100 is fabricated on the laminated substrate 102 as shown in FIG. 3G.

Next, a step of detaching the nitride semiconductor device 100 from the laminated substrate 102 is performed. First, a support substrate 150 for supporting the nitride semiconductor device 100 is attached (FIG. 2B, S222). Then, irradiation with laser light is performed from the amorphous glass substrate 1022 side (FIG. 2B, S224). FIG. 3H schematically shows a stage in which laser light is irradiated.

As the laser light, as described above, a third harmonic of a YAG laser (wavelength 355 nm) or a solid-state laser (wavelength 345 nm) is selected. The laser light having these wavelengths is transmitted through the amorphous glass substrate 1022, the single crystal layer 1024, and the buffer layer 104, and is mostly absorbed by the light absorption layer 106. For example, since the band gap of gallium nitride is 3.4 eV, by using the third harmonic of the YAG laser (355 nm, 3.49 eV), the laser light reaches the light absorption layer 106 without being absorbed by the amorphous glass substrate 1022, the buffer layer 104, and the single crystal layer 1024. On the other hand, since the laser light is mostly absorbed by the light absorption layer 106 and does not reach the nitride semiconductor stack 108, it is possible to prevent deterioration of characteristics of the nitride semiconductor device 100 due to the laser light.

The laser light is pulsed laser light. The light absorption layer 106 generates heat rapidly by being irradiated with laser light having a high energy density in a short time, and at least a part thereof sublimes. As a result, a bond between the nitride semiconductor stack 108 on an upper side of the light absorption layer 106 and the laminated substrate 102 is broken, and the nitride semiconductor device 100 can be detached from the laminated substrate 102. This process is also referred to as laser lift-off.

Note that, in a case where a large-area amorphous glass substrate called mother glass is used as the amorphous glass substrate 1022, a scribing process for dividing the large-area amorphous glass substrate into a plurality of pieces may be performed before the laser lift-off is performed.

Residue may remain on the surface SF of the nitride semiconductor device 100 exposed by detachment due to irradiation with laser light. The residue is a reaction product generated by the light absorption layer 106 being heated to a high temperature, and is, for example, an oxide such as gallium oxide or indium oxide. Therefore, cleaning is performed to remove such residue (FIG. 2B, S226). The cleaning can be performed using a chemical solution such as hydrochloric acid, oxalic acid, or phosphoric acid.

Since the residue does not remain uniformly, an uneven surface as shown in FIG. 1 is formed on the surface SF exposed by the detachment of the nitride semiconductor device 100 by removing the residue.

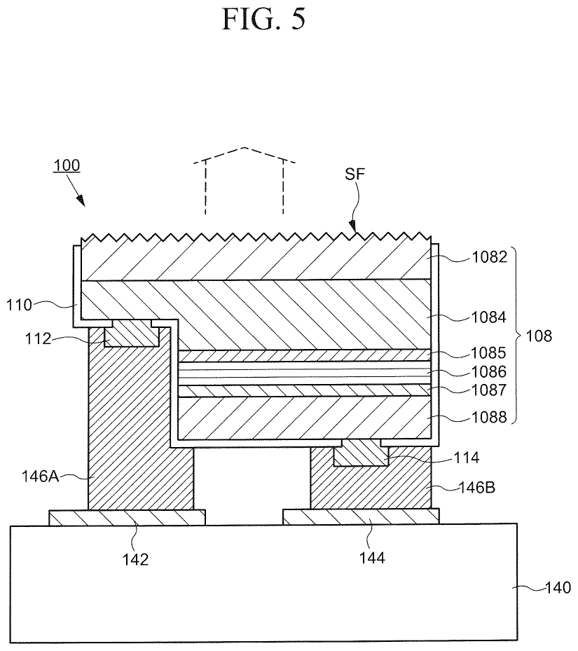

FIG. 5 shows a structure in which the detached nitride semiconductor device 100 is flip-chip mounted via a first bump 146A and a second bump 146B to a substrate 140 on which a first electrode 142 and a second electrode 144 are formed. The nitride semiconductor device 100 has a surface SF, where the nitride semiconductor laminate 108 is peeled off and exposed, as the light-emitting surface. For LED devices formed on sapphire substrates, PSS (Patterned Sapphire Substrate) processing for texturing a sapphire surface serving as a light emitting surface is performed to increase brightness. In contrast, in the nitride semiconductor device 100, since the surface SF has a textured shape, an effect equivalent to that of PSS formed by processing a sapphire substrate can be obtained. That is, in the present embodiment, by cleaning the surface SF exposed after the laser detachment step, an uneven surface can be spontaneously formed, and an effect equivalent to PSS can be obtained.

Note that, although the present embodiment illustratively shows a mode in which one nitride semiconductor device 100 is formed on the laminated substrate 102, productivity can be improved by fabricating a plurality of nitride semiconductor devices 100 on the laminated substrate 102 depending on the size of the laminated substrate 102 and the size of the nitride semiconductor device 100, and individualizing them after detachment.

As described above, the nitride semiconductor device 100 as shown in FIG. 1 can be fabricated. The single crystal layer 1024 remains on the laminated substrate 102 after the nitride semiconductor device 100 has been detached. Although residue remains on the laminated substrate 102 after detachment, the residue can be removed by similar cleaning. The laminated substrate 102 after cleaning can be reused for the manufacture of the nitride semiconductor device 100.

According to the present embodiment, crystallinity of the nitride semiconductor layer can be improved by using the laminated substrate 102 in which the single crystal layer 1024 thinned from the single crystal substrate 103 is bonded to the amorphous glass substrate 1022. Since a substrate suitable for heteroepitaxial growth of a nitride semiconductor layer such as gallium nitride can be selected as the single crystal substrate 103, a nitride semiconductor layer having high crystallinity can be formed on the amorphous glass substrate 1022. Since the single crystal layer 1024 is thermally and chemically stable and is bonded to the amorphous glass substrate 1022 by direct bonding, it can be reused after the nitride semiconductor device 100 is detached. The nitride semiconductor device 100 that has been peeled off from the laminated substrate 102 has an uneven structure on the peeled and exposed surface, and this surface can be used as a light emitting surface to increase the light extraction efficiency.

### Second Embodiment

The present embodiment describes a manufacturing process in which a micro-LED chip is fabricated as the nitride semiconductor device 100 on the laminated substrate 102, and the micro-LED chip is mounted on a substrate on which circuits of a display device are formed, called a backplane. The nitride semiconductor device 100 according to the present embodiment is a light emitting device, more specifically an LED, and more particularly a micro-LED. Note that the micro-LED refers to an LED chip having a chip size of several micrometers or more and 100 μm or less.

As described with reference to FIG. 2A in the first embodiment, steps from step S200 of bonding the single crystal layer 1024 to the amorphous glass substrate 1022 to step S220 of performing contact annealing are performed to fabricate the nitride semiconductor device (micro-LED chip) 100 on the laminated substrate 102. A plurality of nitride semiconductor devices (micro-LED chip) 100 can be fabricated on the laminated substrate 102 at intervals corresponding to a pixel pitch of a display device. Note that, in the present embodiment, the plurality of nitride semiconductor devices (micro-LED chip) 100 are assumed to be blue LEDs that emit blue light.

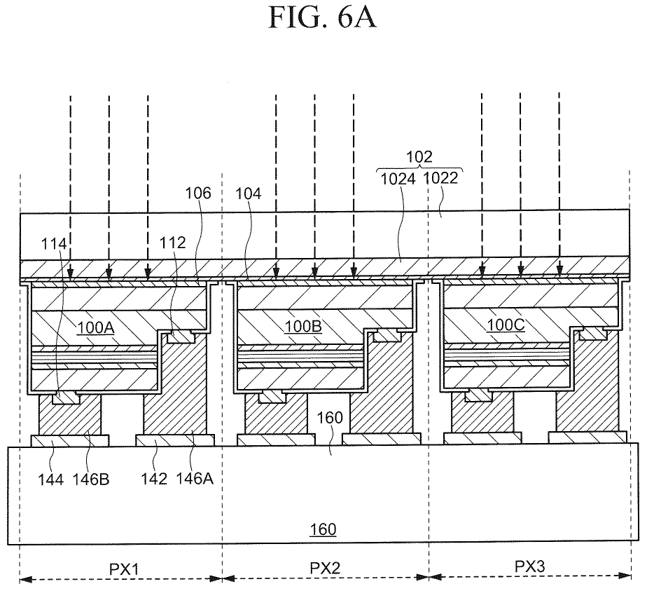

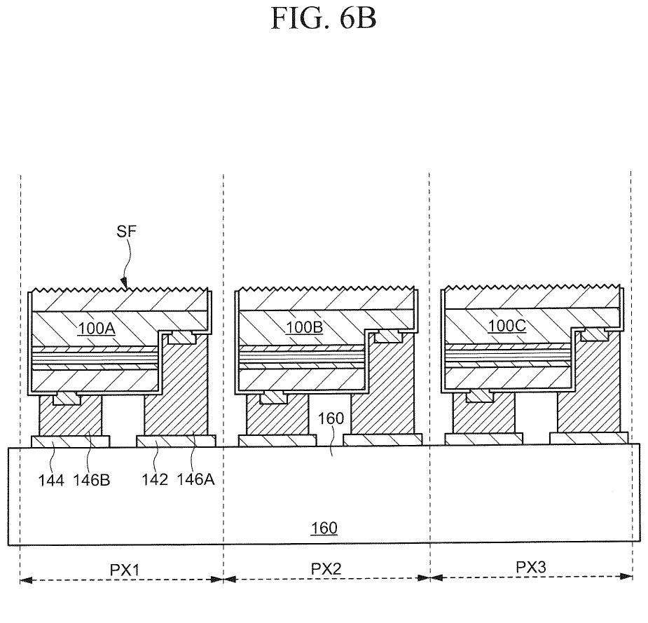

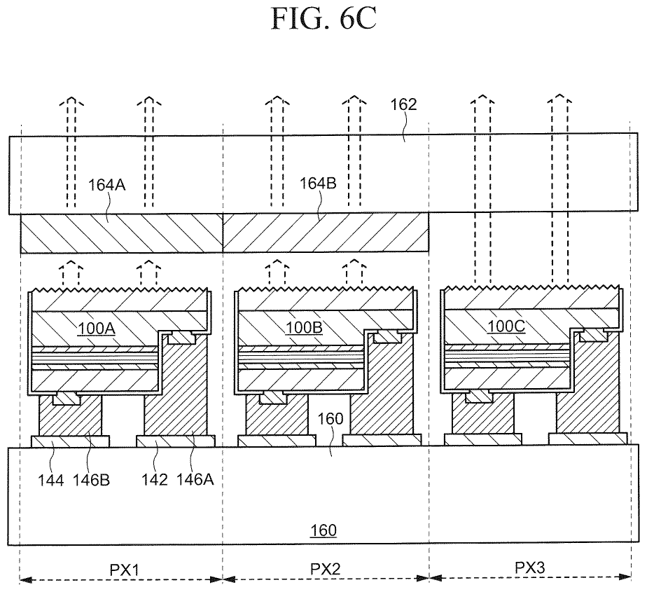

A step of bonding the nitride semiconductor device (micro-LED chip) 100 formed on the laminated substrate 102 to a backplane substrate 160 is performed (FIG. 2C, S226). FIG. 6A shows a state in which the laminated substrate 102, on which a first nitride semiconductor device (first micro-LED chip) 100A, a second nitride semiconductor device (second micro-LED chip) 100B, and a third nitride semiconductor device (third micro-LED chip) 100C are formed, bonded to the backplane substrate 160. Note that the backplane substrate 160 refers to a substrate on which circuits forming pixels (pixel circuits) and circuits driving pixels (drive circuits) are formed.

The backplane substrate 160 is provided with a region where a first pixel PX1 is formed, a region where a second pixel PX2 is formed, and a region where a third pixel PX3 is formed. In the first pixel PX1 of the backplane substrate 160, a first electrode 142 and a second electrode 144 are provided in alignment with the arrangement of the n-electrode 112 and the p-electrode 114 of the first nitride semiconductor device (first micro-LED chip) 100A. The configurations of the first electrode 142 and the second electrode 144 are the same for the second pixel PX2 and the third pixel PX3. In the first pixel PX1, the n-electrode 112 and the first electrode 142 are connected by a first bump 146A, and the p-electrode 114 and the second electrode 144 are connected by a second bump 146B. The same applies to the second pixel PX2 and the third pixel PX3.

In this state, irradiation with laser light is performed from the amorphous glass substrate 1022 side to perform laser lift-off (FIG. 2C, S228). FIG. 6A schematically shows a stage in which laser light is irradiated. As the laser light, a third harmonic of a YAG laser (wavelength 355 nm) or a solid-state laser (wavelength 345 nm) is used, similar to the first embodiment. The irradiation with laser light need not be performed by irradiating the entire surface of the amorphous glass substrate 1022 simultaneously but may be performed by scanning a laser beam condensed into a spot shape, a rectangular shape, or a linear shape by an optical system so that the entire surface of the laminated substrate 102 is irradiated with the laser light.

Through this process, the first nitride semiconductor device (first micro-LED chip) 100A, the second nitride semiconductor device (second micro-LED chip) 100B, and the third nitride semiconductor device (third micro-LED chip) 100C are detached from the laminated substrate 102 and enter a state of being weakly bonded to the backplane substrate 160 via the first bumps 146A and the second bumps 146B.

Thereafter, pressure is applied and a heat treatment is performed to firmly bond the first nitride semiconductor device (first micro-LED chip) 100A, the second nitride semiconductor device (second micro-LED chip) 100B, and the third nitride semiconductor device (third micro-LED chip) 100C to the backplane substrate 160 (FIG. 2C, S230).

Then, a process is performed to clean the surfaces SF exposed by the detachment of the first nitride semiconductor device (first micro-LED chip) 100A, the second nitride semiconductor device (second micro-LED chip) 100B, and the third nitride semiconductor device (third micro-LED chip) 100C from the laminated substrate 102 to remove residue (FIG. 2C, S232). Through this process, as shown in FIG. 6B, an uneven surface is formed on the surfaces SF of the first nitride semiconductor device (first micro-LED chip) 100A, the second nitride semiconductor device (second micro-LED chip) 100B, and the third nitride semiconductor device (third micro-LED chip) 100C, as described in the first embodiment.

Next, a wavelength conversion layer is formed for predetermined pixels (FIG. 2C, S234). In the present embodiment, it is assumed that the first pixel PX1 of the backplane substrate 160 is a pixel corresponding to red, the second pixel PX2 is a pixel corresponding to green, and the third pixel PX3 is a pixel corresponding to blue. As described above, the first nitride semiconductor device (first micro-LED chip) 100A, the second nitride semiconductor device (second micro-LED chip) 100B, and the third nitride semiconductor device (third micro-LED chip) 100C are all devices that emit blue light.

Therefore, as shown in FIG. 6C, a first wavelength conversion layer 164A that converts blue light into red light is provided in the first pixel PX1, and a second wavelength conversion layer 164B that converts blue light into green light is provided in the second pixel PX2. Since the third pixel PX3 is a pixel corresponding to blue, a wavelength conversion layer is not particularly required, and a configuration is adopted in which light is emitted as it is. Note that the first wavelength conversion layer 164A and the second wavelength conversion layer 164B may be formed directly on light emitting surfaces of the first nitride semiconductor device (first micro-LED chip) 100A and the second nitride semiconductor device (second micro-LED chip) 100B, or as shown in FIG. 6C, a sealing substrate 162 may be disposed, and the first wavelength conversion layer 164A and the second wavelength conversion layer 164B may be formed on the sealing substrate 162. As the first wavelength conversion layer 164A and the second wavelength conversion layer 164B, for example, wavelength conversion layers using a quantum dot material can be used.

The first nitride semiconductor device (first micro-LED chip) 100A, the second nitride semiconductor device (second micro-LED chip) 100B, and the third nitride semiconductor device (third micro-LED chip) 100C according to the present embodiment have excellent crystallinity, similar to the nitride semiconductor device shown in the first embodiment, and can achieve improved light extraction efficiency because the light emitting surfaces are textured. Therefore, a display device with a wide dynamic range can be provided.

### Third Embodiment

The present embodiment shows an example of fabricating the nitride semiconductor device 100 on a laminated substrate 102B in which the single crystal layer 1024 is produced from a ScAlMgO₄ single crystal substrate.

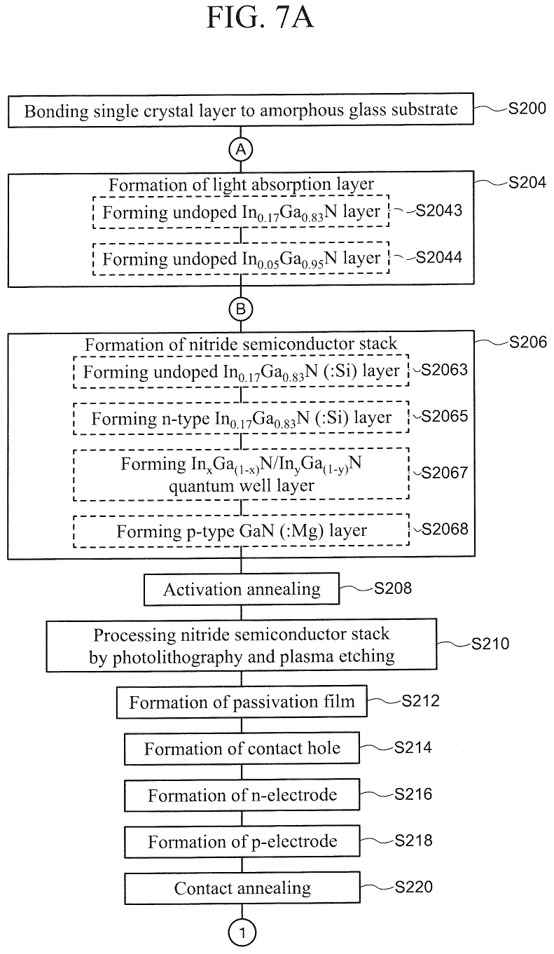

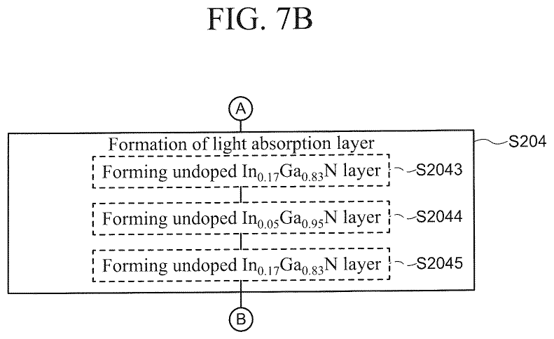

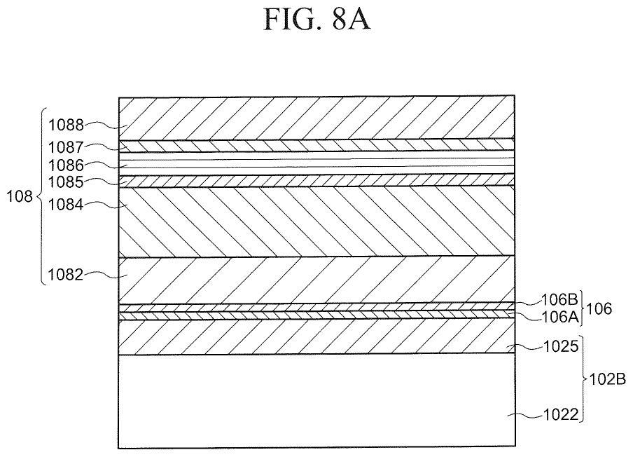

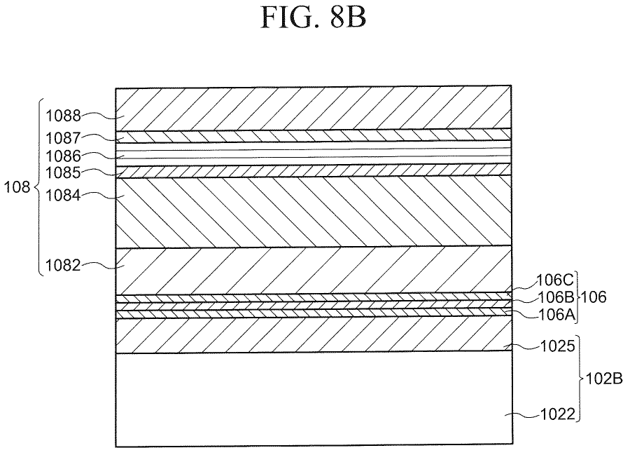

FIG. 7A shows a flowchart illustrating a method of manufacturing the laminated substrate 102B and the nitride semiconductor device 100 according to the present embodiment. Further, FIG. 8A shows a cross-sectional view of a stage of forming the nitride semiconductor stack 108 starting from the light absorption layer 106.

In the present embodiment, a ScAlMgO₄ single crystal layer 1025 is bonded onto the amorphous glass substrate 1022 (FIG. 7A, S200). The light absorption layer 106 is formed of an indium gallium nitride layer on the ScAlMgO₄ single crystal layer 1025 (FIG. 7A, S204). The light absorption layer 106 is formed of a plurality of indium gallium nitride layers having different indium ratios. Specifically, an undoped indium gallium nitride (In_{0.17}Ga_{0.83}N) layer is formed as the first light absorption layer 106A.

Since the undoped indium gallium nitride (In_{0.17}Ga_{0.8}3N) formed as the first light absorption layer 106A lattice-matches with the ScAlMgO₄ single crystal layer 1025, it is suitable for forming an indium gallium nitride (InGaN)-based light-emitting diode emitting light with high efficiency in a green to red band thereon. In the light absorption layer 106, undoped indium gallium nitride (In_{0.05}Ga_{0.95}N) having a different ratio of indium (In) may be further formed as a second light absorption layer 106B.

The nitride semiconductor stack 108 is formed on such a light absorption layer 106 (FIG. 7A, S204). In the nitride semiconductor stack 108, from the light absorption layer 106 side, an undoped indium gallium nitride (In_{0.17}Ga_{0.83}N) layer is formed as an undoped nitride semiconductor layer 1082 (FIG. 7A, S2063), an n-type indium gallium nitride (In_{0.17}Ga_{0.83}N:Si) layer is formed as an n-type nitride semiconductor layer 1084 (FIG. 7A, S2065), an InₓGa₁₋ₓN/In_{y}Ga_{1-y}N quantum well layer is formed as a light emitting layer 1086 (FIG. 7A, S2067), and a p-type GaN:Mg layer is formed as a p-type nitride semiconductor layer 1088 (FIG. 7A, S2068). From the light absorption layer 106 through the undoped nitride semiconductor layer 1082 to the n-type nitride semiconductor layer 1084, it is preferable that a ratio of indium (In) approaches a ratio of indium (In) of the light emitting layer 1086 as it approaches the light emitting layer 1086.

Through such steps, the laminated substrate 102B, the light absorption layer 106 (106A, 106B), and the nitride semiconductor stack 108 having a structure as shown in FIG. 8A can be formed.

The light absorption layer 106 may be formed by stacking a plurality of layers having different indium (In) ratios. For example, as shown in the flowchart in FIG. 7B, a first light absorption layer (In_{0.17}Ga_{0.83}N) (S20243), a second light absorption layer (In_{0.05}Ga_{0.95}N) (S20244), and a third light absorption layer (In_{0.10}Ga_{0.90}N) (S20245) may be stacked as the light absorption layer 106. Through such a process, as shown in FIG. 8B, a structure in which a first light absorption layer 106A, a second light absorption layer 106B, and a third light absorption layer 106C are stacked can be obtained. Subsequent steps are similar to the steps shown in FIG. 7A.

The subsequent steps are the same as those in the first embodiment, and a nitride semiconductor device can also be fabricated in the present embodiment. In addition, a display device using micro-LEDs can be fabricated by following the steps of the second embodiment.

In the present embodiment, since the light absorption layer 106 formed of In_{0.17}Ga_{0.83}N on the ScAlMgO₄ single crystal layer 1025 can serve as a base layer for the InₓGa₁₋ₓN/In_{y}Ga_{1-y}N quantum well layer formed as the light emitting layer 1086, a light-emitting diode that emits light with high efficiency in a green to red band can be realized.

As described above, the configurations and manufacturing methods of the nitride semiconductor device shown in the respective embodiments can be implemented in appropriate combinations as long as they are not mutually inconsistent. Further, those in which a person skilled in the art has appropriately added, deleted, or design-changed components, or added, omitted, or changed conditions of steps based on the respective embodiments are also included in the scope of the present invention, provided that they include the gist of the present invention.

Even if there are other advantageous effects different from those brought about by each of the above-described embodiments, those that are apparent from the description in the present specification or those that can be easily predicted by a person skilled in the art are naturally understood to be brought about by the present invention.

What is claimed is:

1. A method for manufacturing a nitride semiconductor device, the method comprising:
bonding a single crystal layer to an amorphous glass substrate;
forming a light absorbing layer on the single crystal layer;
forming a nitride semiconductor stack on the light absorbing layer;
irradiating laser light from a side of the amorphous glass substrate opposite to the single crystal layer side to separate the nitride semiconductor stack from the single crystal layer, thereby exposing a surface of the nitride semiconductor stack on the single crystal layer side; and
cleaning the exposed surface of the nitride semiconductor stack,
wherein forming the nitride semiconductor stack includes forming at least one gallium nitride-based semiconductor layer on the light absorbing layer, and
the light absorbing layer is formed of a material having a light absorption band for the laser light and allowing heteroepitaxial growth of the gallium nitride-based semiconductor layer.

2. The method according to claim 1, wherein the light absorbing layer is formed of a material selected from the group consisting of InₓGa₁₋ₓN (0.05≤x≤0.25), ZnGeₓSn₁₋ₓN₂ (0.60≤x≤0.90), 4H-SiC, and 6H-SiC.

3. The method according to claim 1, wherein the single crystal layer is a single crystal sapphire substrate or a ScAlMgO₄ single crystal layer.

4. The method according to claim 1, wherein the laser light has an oscillation wavelength at 345 nm or 355 nm.

5. The method according to claim 1, wherein the light absorbing layer is formed of a material selected from the group consisting of InₓGa₁₋ₓN (0.05≤x≤0.25), ZnGeₓSn₁₋ₓN2 (0.60≤x≤0.90), 4H-SiC, and 6H-SiC on a single crystal sapphire substrate or a ScAlMgO₄ single crystal layer.

6. The method according to claim 1, wherein the light absorbing layer is formed of a material selected from the group consisting of InₓGa₁₋ₓN (0.05≤x≤0.25), ZnGeₓSn₁₋ₓN2 (0.60≤x≤0.90), 4H-SiC, and 6H-SiC, and after forming the nitride semiconductor stack, the laser light having an oscillation wavelength at 345 nm or 355 nm is irradiated.

7. The method according to claim 1, wherein the light absorbing layer is formed of a plurality of light absorbing layers.

8. The method according to claim 7, wherein forming the plurality of light absorbing layers includes forming a first light absorbing layer on the single crystal layer and a second light absorbing layer on the first light absorbing layer, and wherein the first light absorbing layer and the second light absorbing layer are InₓGa₁₋ₓN (0.05≤x≤0.25), and a proportion of In in the second light absorbing layer is lower than a proportion of In in the first light absorbing layer.

9. The method according to claim 1, wherein cleaning the exposed surface of the nitride semiconductor stack includes roughening the exposed surface.

10. The method according to claim 1, wherein after the nitride semiconductor stack is separated, a surface of the single crystal layer is cleaned, and the amorphous glass substrate to which the single crystal layer is bonded is reused.
